(19) United States
(12) Patent Application Publication
(10) Pub. No.: US 2025/0232995 A1
(43) Pub. Date: Jul. 17, 2025

(54) Transfer System and Semiconductor Manufacturing Method

(71) Applicant: Tokyo Electron Limited, Tokyo (JP)

(72) Inventor: Hikaru OZONE, Yamanashi (JP)

(21) Appl. No.: 19/005,674

(22) Filed: Dec. 30, 2024

(30) Foreign Application Priority Data
Jan. 12, 2024 (JP) 2024-003462

(51) Int. Cl. H01L 21/677; H01F 7/20

(52) U.S. Cl. CPC H01L 21/67709; H01F 7/206

(57) ABSTRACT

A transfer system used in a semiconductor manufacturing device in which a moving body having a magnet moves while being levitated from a floor by a magnetic force to transfer a substrate to a processing module for processing the substrate is provided. The transfer system comprises: a through-hole forming member having a through-hole formed in a vertical direction; a blocking member that blocks the through-hole to form the floor; a housing of which bottom wall serving as the floor and of which inside is evacuated to create a vacuum atmosphere in a moving area of the moving body that is formed on the floor; a plurality of electromagnets provided inside the floor to move the moving body; and magnetic sensors disposed inside the floor at positions overlapping the through-hole forming member and the blocking member in plan view, and configured to detect a magnetic force of the magnet.

### CROSS-REFERENCE TO RELATED APPLICATIONS

This application claims priority to Japanese Patent Application No. 2024-003462 filed on Jan. 12, 2024, the entire contents of which are incorporated herein by reference.

### TECHNICAL FIELD

The present disclosure relates to a transfer system and a semiconductor manufacturing method.

### BACKGROUND

In a semiconductor manufacturing device that processes a semiconductor manufacturing substrate such as a semiconductor wafer (hereinafter, also referred to as “wafer”), the substrate is transferred between a carrier accommodating wafers and a processing module. It is being studied that the semiconductor manufacturing device has a configuration in which a moving body that transfers the substrates moves while being levitated from a floor by magnetic force in order to transfer the substrate in a clean environment. Japanese Laid-open Patent Publication No. 2014-531189 discloses that a moving body that is combination of magnets moves while being levitated from a floor provided with an electromagnet.

### SUMMARY

The present disclosure provides a technique capable of increasing the strength of the floor and preventing problems related to position detection of a moving body in the case of transferring a substrate by moving the moving body by magnetic force in a vacuum atmosphere above the floor.

One exemplary disclosure relates to a transfer system. The transfer system is used in a semiconductor manufacturing device in which a moving body having a magnet moves while being levitated from a floor by a magnetic force to transfer a substrate to a processing module for processing the substrate. The transfer system comprises: a through-hole forming member having a through-hole formed in a vertical direction; a blocking member that blocks the through-hole to form the floor; a housing of which bottom wall serving as the floor and of which inside is evacuated to create a vacuum atmosphere in a moving area of the moving body that is formed on the floor; a plurality of electromagnets provided inside the floor to move the moving body; and magnetic sensors disposed inside the floor at positions overlapping the through-hole forming member and the blocking member in plan view, and configured to detect a magnetic force of the magnet.

### BRIEF DESCRIPTION OF THE DRAWINGS

FIG. 1 is a plan view showing one embodiment of a semiconductor manufacturing apparatus including a transfer system.

FIG. 2 is a perspective view of a floor and a moving body that transfers a wafer in the transfer system.

FIG. 3 is a side view of a magnet unit constituting the floor and the moving body.

FIG. 4 is a plan view of the floor.

FIG. 5 is a perspective view of a frame constituting the floor.

FIG. 6 is an exploded perspective view of the floor.

FIG. 7 is a schematic plan view of a floor of a transfer system according to a second comparative embodiment.

FIG. 8 is a schematic plan view of a floor of a transfer system according to an embodiment.

FIG. 9 is a vertical side view showing a first modification of the floor.

FIG. 10 is a plan view showing the first modification of the floor.

FIG. 11 is a vertical side view showing a second modification of the floor.

FIG. 12 is a plan view showing the second modification of the floor.

### DETAILED DESCRIPTION

### <Semiconductor Manufacturing Apparatus>

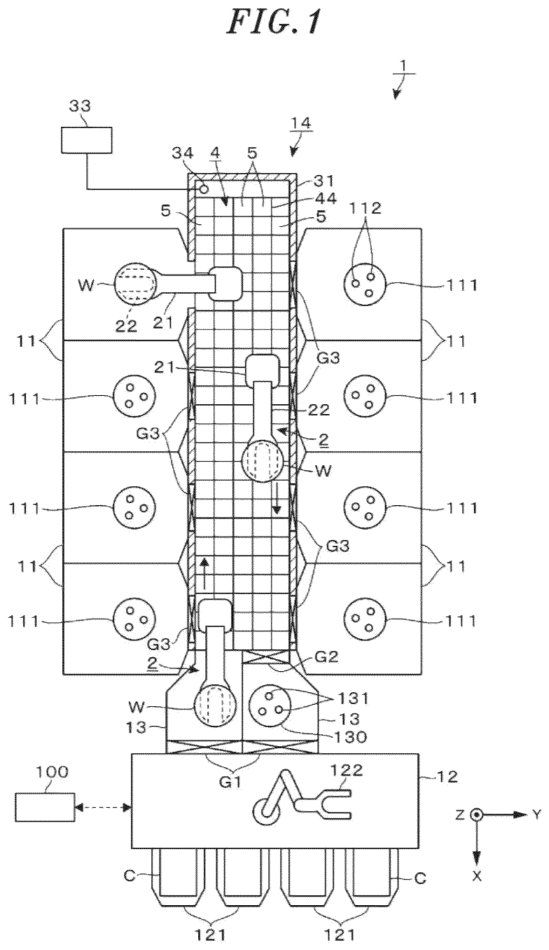

Hereinafter, a semiconductor manufacturing apparatus 1, which is one embodiment of a semiconductor manufacturing apparatus including a transfer system of the present disclosure, will be described with reference to the plan view of FIG. 1. The semiconductor manufacturing apparatus 1 is disposed in a clean room in a semiconductor manufacturing factory, and thus is placed in an atmospheric atmosphere. As shown in FIG. 1, in the semiconductor manufacturing apparatus 1, an atmospheric transfer chamber 12, load-lock modules 13, and a transfer system 14 are arranged along the front-rear direction. In addition, a plurality of processing modules 11 are disposed on the left and right sides of the transfer system 14.

Hereinafter, in the semiconductor manufacturing apparatus 1, the horizontal front-rear direction is set as “X direction,” the left-right direction intersecting the front-rear direction in a horizontal direction is set as “Y direction.” In the front-rear direction, the atmospheric transfer chamber 12 side is set as a front side, and the transfer system 14 side is set as a rear side. In addition, the vertical direction is set as “Z direction.” Further, in order to distinguish one side from the other side in the X direction, positive and negative signs may be assigned. In other words, the +X direction and the −X direction may indicate opposite directions. Similarly, the Y direction and the Z direction may be assigned with positive and negative signs.

A load port 121 on which a carrier C accommodating wafers W to be processed is mounted is disposed in front of the atmospheric transfer chamber 12. The carrier C is, for example, a front opening unified pod (FOUP). Further, the load-lock modules 13 are connected to the rear side of the atmospheric transfer chamber 12. In this example, a plurality of load-lock modules 13 (e.g., two load-lock modules 13) are disposed side by side in the left-right direction.

The atmospheric transfer chamber 12 is maintained in an atmospheric (normal pressure) atmosphere, and a transfer mechanism 122 is disposed therein to transfer the wafer W between the carrier C and the load-lock modules 13. The inner atmosphere of the load-lock modules 13 can be switched between an atmospheric atmosphere and a vacuum atmosphere, and includes a transfer stage 130 on which the wafer W is placed, and lift pins 131. The lift pins 131 are provided to be able to protrude and retract from the stage 130.

The processing module 11 is a module for processing the wafer W. In this example, the processing module 11 is decompressed to a vacuum atmosphere by a vacuum exhaust mechanism (not shown), and is configured to process the wafer W in the vacuum atmosphere. In each processing module 11, a placing table 111 and the lift pins 112 are provided. The lift pins 112 can protrude and retract from the placing table 111. The wafer W is subjected to predetermined processing while being placed on the placing table 111. The processing performed on the wafer W includes etching, film formation, annealing, ashing, and the like.

The transfer system 14, which will be described in detail later, transfers the wafer W in a vacuum atmosphere. In FIG. 1, notations G1, G2, and G3 denote gate valves interposed between the modules. The gate valves G1 to G3 are closed except when it is necessary to transfer the wafer W between the modules and between the transfer system 14 and each module connected to the transfer system 14, thereby separating the atmospheres of the modules.

### <Controller>

The semiconductor manufacturing apparatus 1 includes a controller 100 that is a computer. The controller 100 includes a program including steps (commands) for transferring and processing the wafer W, and the controller 100 transmits control signals to individual components of the semiconductor manufacturing apparatus 1 based on the program. By using the control signals, the pressures of the load-lock modules 13, the transfer system 14, and the processing module 11, the operation of each transfer mechanism including the operation of the moving body 2 to be described later, and the operation of the processing modules 11 are controlled, and the transfer and processing of the wafer W shown in a transfer example to be described later are controlled. The program is stored in a storage medium such as a hard disk, a compact disk, a magneto-optical disk, or a memory card, and is installed in the controller 100 from the storage medium.

Hereinafter, a transfer example of the wafer W in the semiconductor manufacturing apparatus 1 will be described. The wafer W in the carrier C placed on the load port 121 is transferred to the load-lock module 13 maintained in an atmospheric environment by the transfer mechanism 122. After the inner atmosphere of the load-lock module 13 is switched from an atmospheric atmosphere to a vacuum atmosphere, the wafer W in the load-lock module 13 is transferred to the processing module 11 for processing the wafer W via a transfer system 14 to be described in detail later. In the processing module 11, the wafer W placed on the placing table 111 is heated, if necessary, to a preset temperature. If a processing gas supply part is provided, a processing gas is supplied into the processing module 11. In this manner, desired processing is performed on the wafer W.

After the wafer W is processed, the wafer W is transferred in a reverse order of the operation of transferring the wafer W to the processing module 11, and the wafer W is returned from the processing module 11 to the load-lock module 13. After the inner atmosphere of the load-lock module 13 is switched to the atmospheric atmosphere, the wafer W is returned to a specific carrier C by the transfer mechanism 122. The wafer W may be transferred to only one processing module 11 and processed therein from when it is transferred from the load-lock module 13 to the transfer system 14 until it is returned to the load-lock module 13. Alternatively, the wafer W may be transferred between the plurality of processing modules 11 and processed in each processing module 11.

### <Overview of Configuration of Transfer System>

The overview of the configuration of the transfer system 14 will be described. The transfer system 14 includes a housing 31 formed in a rectangular shape elongated in the X direction. The length of the short side of the housing 31 is large enough to allow the moving bodies 2 to be described later to be arranged side by side without interfering with each other. An exhaust port 34 is opened in the housing 31. An exhaust mechanism 33 including a vacuum pump or the like performs an exhaust operation through the exhaust port 34, and the inside of the housing 31 is maintained in a vacuum atmosphere of, for example, 300 Pa or less. An opening for transferring the wafer W is disposed in the sidewall of the housing 31, and is opened and closed by the gate valves G2 and G3 described above. The moving body 2 provided with a magnet is placed on the floor 4 constituting the bottom wall of the housing 31.

A plurality of electromagnets are disposed on the floor 4. By using the repulsive force between the electromagnets and the magnets of the moving body 2, the moving body 2 moves while floating from the floor 4, and transfers the wafer W between the load-lock modules 13 and the processing modules 11, and between the processing modules 11. By controlling the operation of the moving body 2, the movement in the Z direction or the direction change due to the rotation around the Z axis (vertical axis) in addition to the movement in the XY plane are also performed.

The space above the floor 4 in the housing 31 is configured as a moving space 30 where the moving body 2 moves. Further, the floor 4 is provided with a plurality of Hall elements 63, which are magnetic sensors, in addition to the electromagnets. The Hall elements 63 detect the magnetic force of the magnets 23 of the moving body 2. Based on the detection result, the controller 100 detects the position of a magnet unit 24 (to be described later), which is a set of magnets 23, according to a predetermined algorithm, and further detects the position of the moving body 2. By performing feedback control of the position of the moving body 2, the moving body 2 is located at a desired position and moves along a desired path.

### <Moving Body>

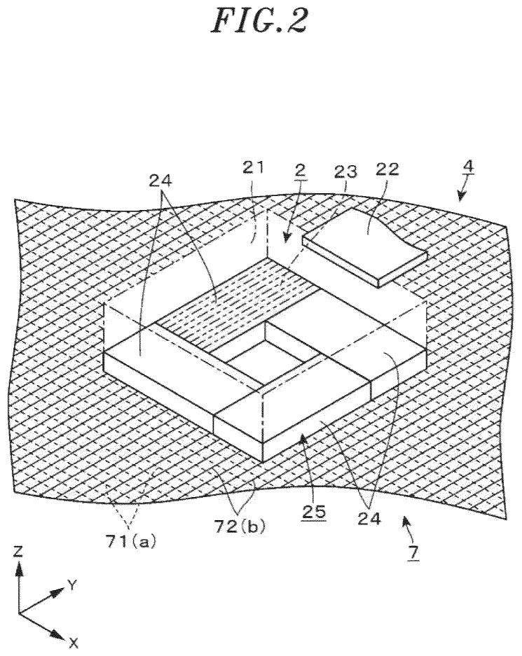

The moving body 2 will be described with reference to the perspective view of FIG. 2. The moving body 2 includes a main body 21 and a substrate holder 22 that projects laterally from the main body 21. The wafer W is supported on the substrate holder 22. The main body 21 includes four magnet units 24, each having nine magnets 23. The magnets 23 are permanent magnets, and have a rectangular parallelepiped shape. In the magnet units 24, the magnets 23 are linearly arranged in a horizontal direction. Adjacent magnets 23 are in contact with each other, thereby forming a flat rectangular parallelepiped with the direction perpendicular to the arrangement direction of the magnets 23 as the longitudinal direction.

In the arrangement of the nine magnets 23 forming the magnet unit 24, the length of the magnets 23 located at both ends is ½ of the length of the other magnets 23. In FIG. 2, for convenience of illustration, the boundary between the magnets 23 of only one of the four magnet units 24 is indicated by dash dotted lines, but the magnet units 24 are configured in the same manner.

The four magnet units 24 are arranged along the sides of a square in plan view, and both ends thereof are connected to other magnet units 24 to form a rectangular ring-shaped body 25. The following is specific description of the connection between the magnet units 24. Two adjacent magnet units 24 are connected such that the longitudinal end of one magnet unit 24 is located on the extension line in the longitudinal direction of the other magnet unit 24. Due to the above-described connection of the magnet units 24, the ring-shaped body 25 is rotationally symmetrical around the vertical axis (Z axis) in a horizontal state.

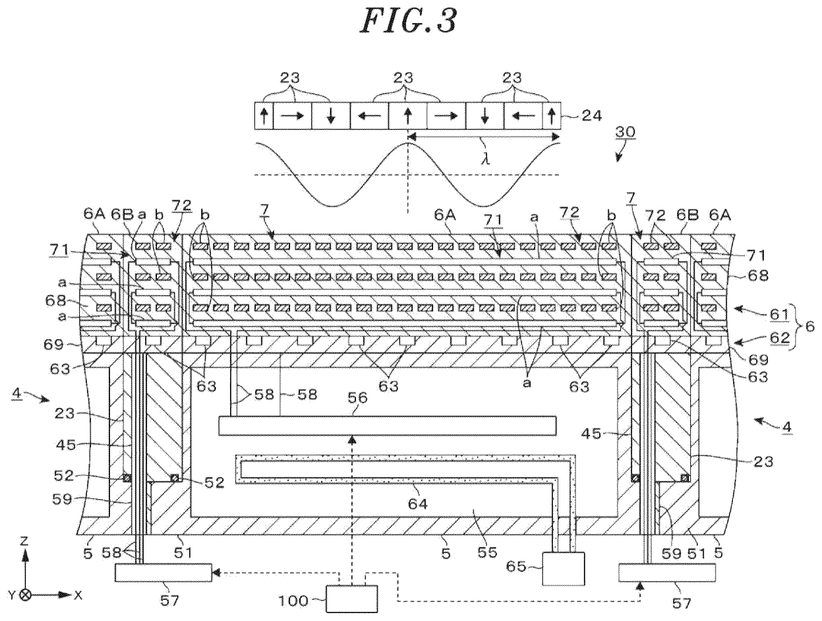

The magnet unit 24 will be further described with reference to FIG. 3 showing the longitudinal side view of the magnet unit 24 and the floor 4. The magnet unit 24 will be described representatively on the assumption that the arrangement direction of the magnets 23 of one of the four magnet units 24 coincides with the X direction as shown in FIG. 3. In FIG. 3, the directions of the N poles of the nine magnets 23 constituting the magnet unit 24 are indicated by arrows. The magnets 23 are arranged in Halbach arrangement in which the directions of the N poles of adjacent magnets are different from each other by 90°, so that relatively strong magnetic field is formed below the magnet unit 24. Specifically, the magnets 23 are arranged such that the orientations of the N poles are changed periodically when viewed in the arrangement direction of the magnets 23. Further, specifically, the N poles are sequentially oriented in +Z, −X, −Z, +X, +Z, −X, −Z, +X, and +Z directions with respect to the arrangement direction.

Since the magnet unit 24 is configured as described above, the magnetic field having strength distribution that changes to draw two periods of a sine wave when viewed from one end toward the other end in the arrangement direction of the magnets 23 is formed directly below the magnet unit 24, as shown in FIG. 3. The length of one period of the sine wave is indicated as λ.

### <Configuration of Floor>

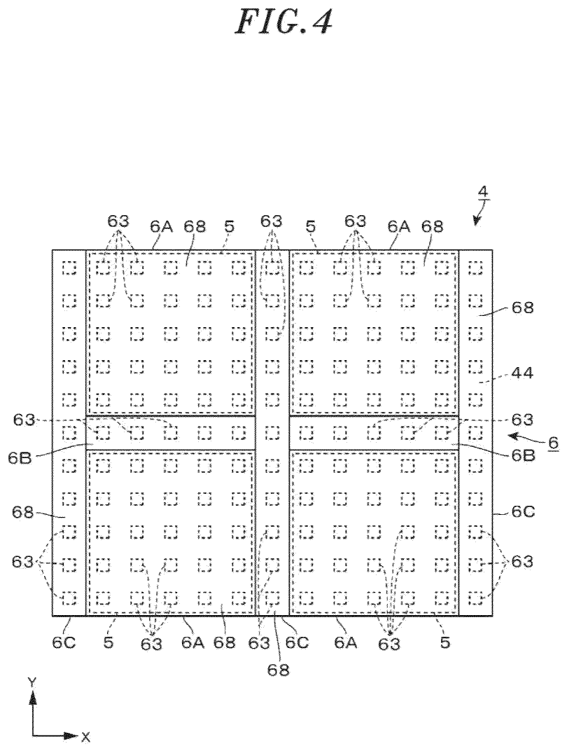

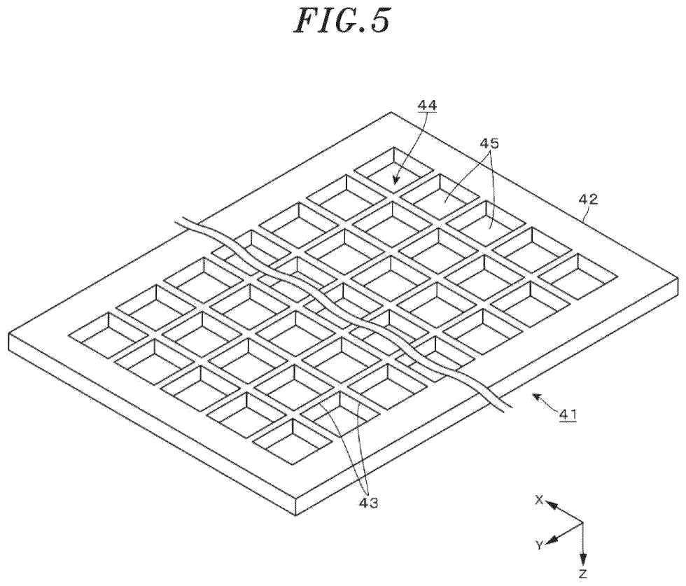

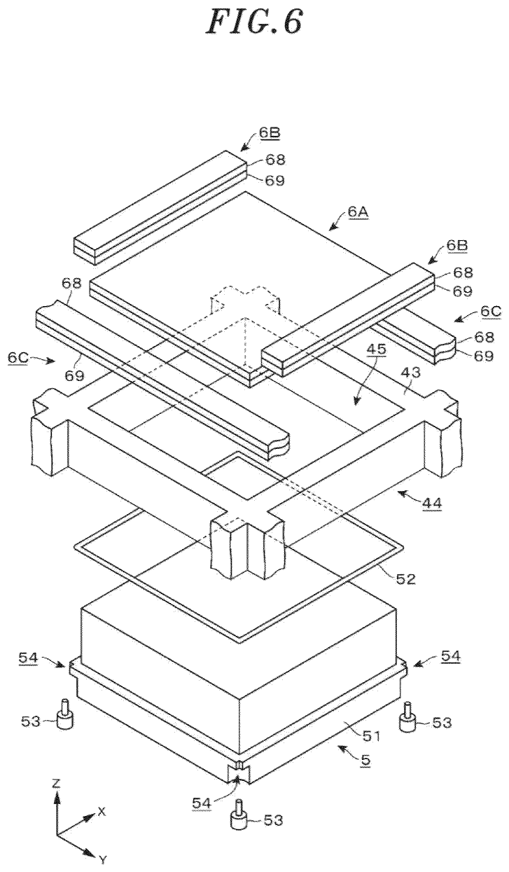

Next, the floor 4 will be described with reference to FIG. 4 that is a plan view showing a part of the floor. The floor 4 includes a frame 41, a plurality of case bodies 5, and a plurality of laminated substrates 6. FIG. 5 is a perspective view of the frame 41, and FIG. 6 is an exploded perspective view showing individual components of the floor 4. FIGS. 5 and 6 will be referred to as appropriately. The frame 41 has an outer frame 42 and a plurality of beams 43. As will be described in detail later, the case body 5 has a hollow structure, but the frame 41 does not have a hollow structure and is stronger than the case body 5. The outer frame 42 is configured as a horizontal rectangular frame to form the edge of the bottom wall of the housing 31, and the short and long sides of the frame are aligned along the X and Y directions, respectively. For example, the lower end of the sidewall of the housing 31 is connected to the upper surface of the outer frame 42.

The beam 43 is formed to extend linearly in the outer frame 42, and both ends of the beam 43 are connected to the inner circumference of the outer frame 42. The plurality of beams 43 extending in the X direction are arranged at equal intervals in the Y direction, and the plurality of beams 43 extending in the Y direction are arranged at equal intervals in the X direction. The beams 43 extending in the X direction and the beams 43 extending in the Y direction are located at the same height, and are connected to each other to form a lattice beam 44. Therefore, an area surrounded by the outer frame 42 is partitioned by the lattice beam 44, and each partitioned area formed a through-hole 45 that opens in the bottom wall of the housing 31 in the Z direction (i.e., the vertical direction). Each through-hole 45 has a square shape in plan view. Although FIG. 1 shows that the exhaust port 34 is opened at the outer frame 42, the opening position of the exhaust port 34 is not limited thereto, and the exhaust port 34 may be opened at the sidewall of the housing 31, for example.

### <Partitioning of Moving Space by Case Body>

The case bodies 5 are inserted into the plurality of through-holes 45 from the bottom side of the frame 41, thereby blocking the through-holes 45. The case body 5 has a quadrilateral shape, and the upper surface thereof has a square shape of which size is substantially the same as that of the through-hole 45. The lower side of the sidewall of the case body 5 protrudes outward from the case body 5 to form a quadrilateral ring-shaped flange 51. A seal member 52, which is a quadrilateral ring-shaped elastic body having a shape corresponding to the shape of the flange 51, is disposed on the flange 51. The upper part of the case body 5 is inserted and fitted into the through-hole 45 from the bottom side of the frame 41, and the portion of the flange 51 outside the area surrounded by the seal member 52 is screwed to the frame 41 from the bottom side. Accordingly, the case body 5 is fixed to the frame 41.

The following is specific description of the configuration related to the screwing and sealing. A ring-shaped groove is formed along the edge of each through-hole 45 at the bottom portion of the frame 41. When the seal member 52 is positioned in the groove, the position thereof is fixed. A notch 54 through which a screw 53 is inserted is formed at the corners of the flange 51. When the screw 53 is screwed into a screw hole formed in the bottom surface of the frame 41, the edge of the notch 54 in the flange 51 overlaps the head of the screw 53. Therefore, by tightening the screws 53, the flange 51 is pressed toward the frame 41, and the seal member 52 is deformed. The seal member 52 is brought into tight contact with the flange 51 by the restoring force thereof. Due to the tight contact, the moving space 30 in the housing 31 is partitioned from the external space of the housing 31, and is sealed against the external space maintained in an atmospheric atmosphere to ensure a vacuum atmosphere. The upper surface of the case body and the upper surface of the frame 41, which are screwed as described above, are located at the same height. Hence, the upper surface of the case body 5 is inserted into the through-hole 45 in plan view. Each of the upper surface of the case body 5 and the upper surface of the frame 41 form a horizontal plane.

### <Description of Laminated Substrate of Floor and Divided Pieces Thereof>

Prior to the description of the internal structure of the case body 5, the case body 5 and a laminated substrate 6 disposed above the frame 41 will be described. The laminated substrate 6 includes the electromagnets and the Hall elements 63 described above, and is disposed in the entire area of the floor 4 where the case body 5 and the lattice beam 44 are provided. The laminated substrate 6 is formed as a laminated body of a coil substrate 61 and a sensor substrate 62. The sensor substrate 62 is stacked on the upper surface of each case body 5 and the upper surface of the lattice beam 44, thereby covering the entire upper surfaces thereof. Further, the coil substrate 61 is stacked on the sensor substrate 62, thereby covering the entire upper surface of the coil substrate 61.

The laminated substrate 6 is divided into a plurality of pieces so that the transfer system 14 can be manufactured easily. In other words, a plurality of substrates (divided pieces) form the laminated substrate 6 that is one large substrate. Specifically, the laminated substrate 6 includes a divided piece 6A that covers the entire upper surface of the case body 5, a divided piece 6B that covers the beams 43 of the lattice beam 44 that extend in the X direction, and a divided piece 6C that covers the beams 43 of the lattice beam 44 that extend in the Y direction.

The divided piece 6A is provided for each case body 5. The divided piece 6A has the same size as that of the upper surface of the case body 5, and covers the entire upper surface thereof. The divided pieces 6B and 6C are formed to have a width that is the same as that of the beam 43. The divided pieces 6C are arranged in the X direction on the beams 43 that extend in the Y direction, and the longitudinal length (length in the Y direction) thereof is appropriately set so as not to hinder the manufacture of the device. The longitudinal length (length in the X direction) of the divided piece 6B is the same as the length of one side of the upper surface of the case body 5 in plan view. Since the divided pieces 6B and 6C are formed as described above, the entire upper surface of the lattice beam 44 is covered by the divided pieces 6B and 6C.

Hereinafter, in each of the divided pieces 6A to 6C, the upper divided piece forming the coil substrate 61 may be referred to as “upper divided piece 68” and the lower divided piece forming the sensor substrate 62 may be referred to as “lower divided piece 69.” The sensor substrate 62 corresponds to a first substrate, and the divided piece thereof, which is the lower divided piece 69, corresponds to a first divided piece. The coil substrate 61 corresponds to a second substrate, and the divided piece thereof, which is the upper divided piece 68, corresponds to a second divided piece. The divided piece 6A disposed on the case body 5 corresponds to one divided piece, and the divided pieces 6B and 6C disposed on the lattice beam 44 correspond to another divided piece.

### <Electromagnet and Hall Element of Floor>

The coil substrate 61 will be described. The coil substrate 61 is provided with a driving coil 7. The driving coil 7 includes a linear A coil 71 indicated by a dashed line in FIG. 2 and a linear B coil 72 indicated by a solid line. The plurality of A coils 71 are spaced apart from one another in the Y direction, and extend along the X direction. The plurality of B coils 72 are spaced apart from one another in the X direction, and extend along the Y direction. Each of the A coil 71 and the B coil 72 forms an electromagnet, and the power supply thereto is controlled individually.

Each of the A coils 71 and the B coils 72 includes coil wires a and b shown in FIG. 3. The coil wires a and b are laminated alternately, for example, and the coil wires a and b laminated horizontally are insulated from each other by an insulating layer (not shown) disposed at the coil substrate 61. Therefore, the coil substrate 61 is a laminated structure of the coil wire a, a coil wire b, and an insulating layer. Further, the number of layers of the coil wires a and b shown in FIG. 3 is an example, and may be changed appropriately, if necessary.

As shown in FIG. 3, the coil wire a is electrically connected to the coil wire a disposed thereabove or therebelow to form a spiral shape when viewed in an X-Z vertical cross section, thereby forming the A coil 71. Similarly, the coil wire b is electrically connected to the coil wire b disposed thereabove or therebelow to form a spiral shape when viewed in a Y-Z vertical cross section, thereby forming the B coil 72. FIG. 2 shows the uppermost coil wires a and b in the A coil 71 and the B coil 72. As described above, the coil substrate 61 is divided into the upper divided pieces 68 to form the divided pieces 6A to 6C, and the A coil 71 and the B coil 72 are included in each of the upper divided pieces 68 forming the divided pieces 6A to 6C. Further, in order to illustrate the A coil 71 and the B coil 72, the thickness of the coil substrate 61 with respect to the sensor substrate 62 is shown larger in FIG. 3 than in FIG. 6.

Hereinafter, the sensor substrate 62 will be described. The plurality of Hall elements 63 are embedded in the upper surface of the sensor substrate 62. The Hall elements 63 are arranged in a matrix shape at intervals in both the X and Y directions. The gaps between adjacent Hall elements 63 in the X direction are equal, and the gaps between adjacent Hall elements 63 in the Y direction are equal. Further, the gaps between adjacent Hall elements 63 in the X direction and the Y direction are also equal. Therefore, as shown in FIG. 4, the Hall elements 63 are arranged to be located at the lattice points of a square lattice in plan view. Further, the square lattice is an imaginary lattice.

By using the Hall elements 63, the magnetic force below the magnet unit 24 shown in FIG. 3 described above is detected, and the position where the intensity distribution of the magnetic field forming the sine wave described in FIG. 3 is formed is identified. Accordingly, the controller 100 detects the XY plane position of the magnet unit 24. Further, the controller 100 detects the position of the magnet unit 24 in the Z direction by identifying the amplitude of the sine wave from the magnetic force detected by the Hall elements 63. The Hall elements 63 are arranged at the lattice points of the square lattice as described above in order to allow the Hall elements 63 to be uniformly distributed on the floor 4 and to prevent calculation required for detecting the position of the magnet unit 24 from becoming complicated.

FIG. 3 showing a wavelength λ of the magnetic field intensity distribution described above will be also referred for description. It is clear from research that it is necessary that three or more Hall elements 63 are included within a range of the wavelength λ by arranging the magnets 23 along the X or Y direction in order to simplify the calculation by arranging the Hall elements 63 according to the lattice points of the square lattice as described above. More specifically, if the wavelength λ is 40 mm, the gap between the centers of adjacent Hall elements 63 in each of the X and Y directions is calculated to be λ=40 mm/3=13.3 mm or less.

FIG. 3 shows an example in which three Hall elements 63 are included within a range of the wavelength λ. In other words, FIG. 3 shows an example in which the relationship of the wavelength λ/3=X or the gap between the Hall elements 63 in the X or Y direction is satisfied. Further, when the wavelength λ and the number of Hall elements 63 have such a relationship, the following Eq. (1) is used to identify the position of the magnet unit 24 described above. Ba, Bb, and Bc in Eq. (1) are the detection values of the magnetic force detected by three Hall elements 63 arranged consecutively in the X or Y direction. Eq. (1) includes, in addition to parameters Zr, λc, and θa, constants 2π/3 and 4π/3 that are determined on the assumption that the relationship of the wavelength λ/3=X or the gap between Hall elements 63 in the X or Y direction is satisfied, and 2 is equal to πλ.

$$Ba + Bb + Bc = 0.71 Br \times {e}^{\frac{Zr}{λ c}} ( cos ( {θ}_{a} ) + cos ( {θ}_{a} + \frac{2 π}{3} ) + cos ( {θ}_{a} + \frac{4 π}{3} ) ) \qquad Eq . ( 1 )$$

As described above, the sensor substrate 62 is divided into the lower divided pieces 69 to form the divided pieces 6A to 6C, and the Hall elements 63 are included in each of the lower divided pieces 69 forming the divided pieces 6A to 6C. As shown in FIG. 4, the Hall elements 63 are arranged to form a square matrix at the lower divided piece 69 forming the divided piece 6A. The Hall elements 63 are arranged in a row along the longitudinal direction at the lower divided pieces 69 forming the divided pieces 6B and 6C.

Further, the upper surface of the case body 5 on which the sensor substrate 62 is disposed and the upper surface of the frame 41 are located at the same height, so that the heights of the lower divided pieces 69 are aligned between the divided pieces 6A to 6C. Therefore, the heights of the Hall elements 63 at the divided pieces 6A, 6B, and 6C are the same. Since the heights of the Hall elements 63 are the same, the detection sensitivity for the magnetic force of the magnet 23 of the moving body 2 becomes uniform in the Hall elements 63, thereby preventing the calculation for detecting the position of the magnet unit 24 from becoming complicated.

Further, the heights of the upper divided pieces 68 forming the coil substrate 61 are the same in the divided pieces 6A to 6C. Therefore, the A coils 71 and the B coils 72 are located higher than the Hall elements 63, and are arranged closer to the moving body 2. With such arrangement, it is possible to apply the buoyancy and the moving force to the moving body 2 with a relatively small amount of power supplied to each coil.

As described above, the driving coils 7 (the A coil 71 and the B coil 72) and the Hall elements 63 are included in each of the divided pieces 6A to 6C of the laminated substrate 6. Since the divided piece 6A is disposed on the upper surface of the case body 5 disposed in the through-hole 45 formed by the lattice beam 44, the driving coils 7 and the Hall elements 63 are disposed at positions overlapping the through-holes 45 in plan view. Further, since the divided pieces 6B and 6C are disposed on the upper surface of the lattice beam 44, the driving coils 7 and the Hall elements 63 are also disposed at positions overlapping the lattice beam 44 in plan view. The frame 41 including the lattice beam 44 is a through-hole forming member, and the case body 5 is a blocking member that blocks the through-hole 45.

### <Inside of Case Body 5>

Referring back to the description of the case body 5, as shown in FIG. 3, a storage space 55 is formed in the case body 5, and a control substrate 56 is disposed in the storage space 55. The control substrate 56 includes a processor, a memory, a program, an input/output interface, and various electronic circuits. The processor includes a central processing unit (CPU), an application-specific integrated circuit (ASIC), a field-programmable gate array (FPGA), or the like. The control substrate 56 is connected to the controller 100 provided outside the housing 31, and is configured to receive control signals from the controller 100, execute programs stored in the memory, and perform operations to be described below.

The control substrate 56 is connected via a cable to a power supply (not shown) provided outside the housing 31. The illustration of the cable and the power supply is omitted. Further, the control substrate 56 is connected via a cable 58 to an upper divided piece 68 and a lower divided piece 69 that constitute the divided piece 6A. A through-hole through which the cable 58 is inserted to make the above-described connection is formed in the upper wall of the case body 5.

The control substrate 56 controls a DC power supplied from the power supply to the driving coils 7 and the Hall elements 63. When the power is supplied to the driving coils 7, the control substrate 56 receives a control signal from the controller 100, and supplies a power to the A coil 71 and/or the B coil 72 selected according to the control signal. The magnetic field is formed on the upper surface of the area where the A coil 71 and the B coil 72 are arranged, and the buoyancy and the moving force are applied to the moving body 2 as described above. Further, the control substrate 56 has a function of transmitting the magnetic detection signal received from the Hall elements 63 to the controller 100. The control substrate 56 is provided for the driving coils 7 and the Hall elements 63, and forms a control device for controlling the operations thereof. Although only three cables 58 are illustrated in the drawing, a desired number of cables are provided to supply a power to each coil, to supply a power to each Hall element 63, and to receive a signal from each Hall element 63.

The storage space 55 of the case body 5 is provided with a channel 64 through which cooling fluid such as water flows. One end and the other end of the channel 64 are drawn out to the outside of the case body 5, and connected to a chiller 65 provided outside the housing 31. A fluid circulation path is formed by the channel 64 and the chiller 65. The fluid whose temperature is controlled by the chiller 65 is supplied to the channel 64. The temperature of the fluid increases due to the absorption of heat from the storage space 55 and the wall of the case body 5. The fluid is supplied to and cooled in the chiller 65, and then supplied to the channel path 64 again. Due to the heat absorption effect of the fluid, the control substrate 56 and the divided pieces 6A are cooled, thereby preventing an increase in the temperature. Further, the divided pieces 6B and 6C are cooled by the fluid via the lattice beam 44 in contact with the case body 5. By cooling the divided pieces 6A to 6C, damage and deterioration of the divided pieces 6A to 6C caused by the heat are prevented, and the gap between the Hall elements 63 is prevented from changing from a design value due to thermal expansion. In other words, a decrease in the detection accuracy of the position of the moving body 2 is prevented.

In addition, a fan may be provided, instead of the channel 64, as a cooling mechanism for cooling the case body 5 and the storage space 55. Specifically, the wall of the case body 5 and the storage space 55 may be cooled by supplying air outside the case body 5 to the inside of the case body 5 by a fan from the bottom side of the case body 5.

### <Additional Description of Lattice Beam, Case Body, and Laminated Substrate>

As shown in FIG. 3, the through-holes 45 are bored in the lattice beam 44 in the Z direction. The through-hole 45 is provided for each of the divided pieces 6B and 6C. In addition, a through-hole 59 is provided in the flange 51 of the case body 5 at a position overlapping the through-hole 45. One end of the cable 58 is connected to the upper divided piece 68 and the lower divided piece 69 that form the divided pieces 6B and 6C. Further, the other end of the cable 58 is drawn out to the outside of the housing 31 through the through-holes 45 and 59, and is connected to the control substrate 57 provided outside the storage space 55 of the case body 5 and outside the housing 31. Further, the illustration of the through-hole 59 of the case body 5 is omitted in drawings other than FIG. 3.

The control substrate 57 has the same configuration as that of the control substrate 56 provided in the storage space 55, and has the same function as that of the control substrate 56 except that the operation control targets are the elements of the divided pieces 6B and 6C, rather than the elements of the divided piece 6A. Further, the controller 100 and the control substrates 56 and 57 can control the power supply to one A coil 71 and one B coil 72 in each of the divided pieces 6A to 6C.

### Comparative Embodiment

In order to describe the advantages of the configuration of the transfer system 14 described above, a transfer system according to a comparative embodiment will be described. In a transfer system according to a first comparative embodiment, the lattice beam 44 is not provided on the floor 4. More specifically, in the first comparative embodiment, the case bodies 5 are adjacent to each other to form the floor 4 of the transfer system. Further, in the first comparative embodiment, the divided pieces 6A are stored in the storage space 55 of the case body 5. In other words, the driving coils 7 and the Hall elements 63 are provided in the storage space 55. The transfer system according to the first comparative embodiment has the same configuration as that of the transfer system 14 except the difference in the configuration of the floor 4 described above. Further, similarly to the transfer system 14, the Hall elements 63 of the first comparative embodiment are arranged at the lattice points of a square lattice on the entire floor 4.

Since, however, the moving space 30 in the housing 31 is maintained in a vacuum atmosphere as described above, a pressure difference occurs between the inside and the outside of the housing 31. Further, since the case body 5 has a hollow structure to store devices such as the control substrate 56, it may be difficult to sufficiently increase the strength of the case body 5. In other words, in the transfer system according to the first comparative embodiment, it is desirable to more reliably prevent deformation and damage of the floor 4 due to the pressure difference between the inside and the outside of the housing 31.

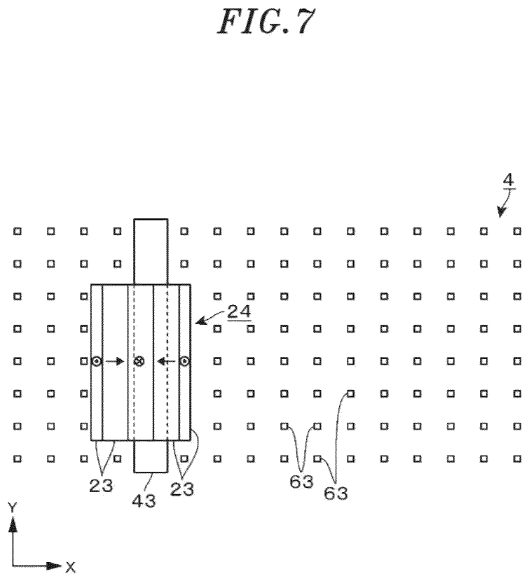

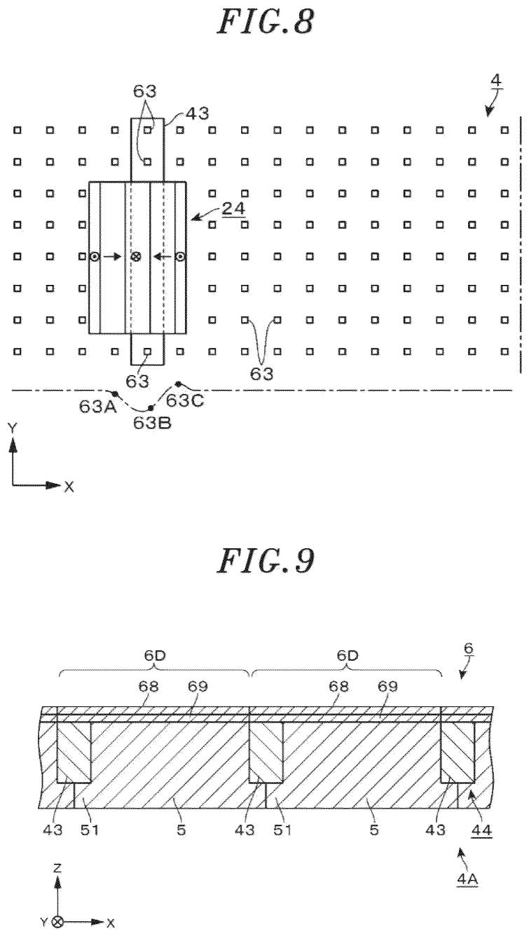

A transfer system according to a second comparative embodiment has a configuration in which the above-described lattice beam 43 is provided in the first comparative embodiment. The second comparative embodiment has the same configuration as that of the first comparative embodiment except that the lattice beam 43 is provided. Therefore, the Hall elements 63 are included only in the storage space 55 of the case body 5. FIG. 7 shows a schematic plan view of the floor 4 of the transfer system according to the second comparative embodiment. FIG. 7 and FIG. 8 to be described later show the magnet unit 24 in a state where the arrangement direction of the magnets 23 coincides with the X direction as in FIG. 3, but only a portion of the magnet unit 24 that forms magnetic force distribution of 1λ is shown. Signs attached to the magnets 23 in the drawing indicate the directions of the N pole.

In the transfer system according to the second comparative embodiment, the lattice beam 44 is provided, so that the floor 4 is reinforced compared to the first comparative embodiment. However, as shown in FIG. 7, the case bodies 5 are separated from each other by the beams 43 forming the lattice beam 44. Therefore, the Hall elements 63 are not arranged at the lattice points of the square lattice, and three or more Hall elements 63 are not included in the area below the magnet unit 24 where magnetic force distribution of 1λ is formed in the X direction. Hence, the calculation required to detect the position of the magnet unit 24 becomes complicated or the calculation becomes impossible.

It is possible to avoid the problem by adjusting the gaps between the Hall elements 63 in the case body 5 such that the Hall elements 63 are arranged at the lattice points of the square lattice on the entire floor 4. However, in order to ensure the sufficient strength of the floor 4, the width of the beams 43 forming the lattice beam 44 needs to be large enough, so that the separation distance of the case bodies 5 may be relatively large. Therefore, the problem may not be solved by adjusting the gaps between the Hall elements 63 in the case body 5.

### <Effects of Transfer System According to Embodiment>

Accordingly, in the transfer system 14 according to the present embodiment, the Hall elements 63 are provided on the lattice beam 44 as well as the case body 5 as described above. Hence, as shown in the schematic plan view of FIG. 8, the Hall elements 63 are arranged on the lattice points of a square lattice on the floor 4, and three Hall elements 63 are included directly below the portion of the magnet unit 24 that forms magnetic force distribution of 1λ. Therefore, in accordance with the transfer system 14, it is possible to ensure sufficient strength for the floor 4, and also possible to detect the position of the moving body 2 by simple calculation and to transfer the wafer W while controlling the position thereof with high accuracy.

Further, the dash-dotted lines in FIG. 8 indicates the magnetic force distribution in the X direction formed by the displayed magnet unit 24, and reference numerals 63A, 63B, and 63C indicate the magnetic force strength detected by the three Hall elements 63 directly below the magnet unit 24 in such magnetic force distribution. The dashed double-dotted lines in FIG. 8 indicate the magnetic force distribution in the Y direction formed by the magnet unit 24. As shown in FIG. 8, the magnetic force distribution is constant in each part.

Further, in the transfer system 14, the Hall elements 63 provided at the case body 5 are arranged on the case body 5, instead of being provided in the storage space 55, to be aligned with the height of the Hall elements 63 provided on the lattice beam 44. Accordingly, it is possible to reliably prevent the calculation of the position detection of the moving body 2 from becoming complicated, as described above.

Further, since the Hall elements 63 are arranged on the base body 5, the driving coils 7 provided at the case body 5 are disposed above the hole elements 63. With this configuration, the magnetic force of the driving coils 7 is prevented from being attenuated by the Hall elements 63 and the lower divided pieces 69 where the Hall elements 63 are provided, so that the buoyancy and the moving force can be applied to the moving body 2 with a smaller amount of power, as described above.

On the other hand, in the second comparative embodiment in which the driving coils 7 are not provided at the lattice beam 44, the moving body 2 passes through an area where the driving coils 7 are not formed while moving laterally, so that the force acting on the moving body 2 may change and the moving body 2 may vibrate. Further, when the moving body 2 passes through an area where the driving coils 7 are not formed, the power supplied to the driving coils 7 in the vicinity of the area is relatively large so that sufficient buoyancy and moving force can be applied to the moving body 2. In other words, in the second comparative embodiment, the power consumption for transferring the wafer W may be large. However, in the transfer system 14, the driving coils 7 are also disposed on the lattice beam 44, so that the occurrence of the above problems can be suppressed.

The driving coils 7 disposed on the lattice beam 44 in the transfer system 14 are located above the Hall elements 63, similarly to the driving coils 7 on the case body 5, and are located at the same height as the driving coils 7 on the case body 5. Since the heights of the driving coils 7 are aligned on the case body 5 and on the lattice beam 44, if the moving body 2 moves in the same manner at different locations on the floor 4, it is unnecessary to change the power supplied to the driving coils 7 for each location. In other words, by aligning the heights of the driving coils 7, the calculation for supplying a power to each driving coil 7 is simplified.

As described above, it is desirable to provide the driving coils 7 and the Hall elements 63 on each of the case body 5 and the lattice beam 44, but the present disclosure is not limited to such a configuration. For example, in the transfer system 14, instead of providing the driving coils 7 and the Hall elements 63 on the case body 5, the driving coils 7 and the Hall elements 63 may be disposed in the case body 5 as in the first and second comparative embodiments. Either the driving coils 7 or the Hall elements 63 may be disposed in the case body 5. Although the above-described advantages are obtained by providing the driving coils 7 above the lattice beam 44, the driving coils 7 may not be provided above the lattice beam 44. In other words, the driving coils 7 may be provided only in the case body 4 or on the case body 5. Further, the driving coils 7 and the Hall elements 63 are not necessarily provided above the lattice beam 44, and the driving coils 7 and the Hall elements 63 may be provided to be embedded in the lattice beam 44.

### <Other Examples of Floor Configuration>

In the floor 4, the laminated substrate 6 including the coil substrate 61 and the sensor substrate 62 is divided into the divided pieces 6A each of which covers each case body 5, and the divided pieces 6B and 6C that cover the lattice beam 44. In other words, a divided piece is formed for each case body 5, and the divided piece for covering the case body 5 is different from the divided piece for covering the lattice beam 44. When the laminated substrate 6 is divided, it is unnecessary to form the divided pieces, and the size of the divided pieces is arbitrary.

### <First Modification of Floor>

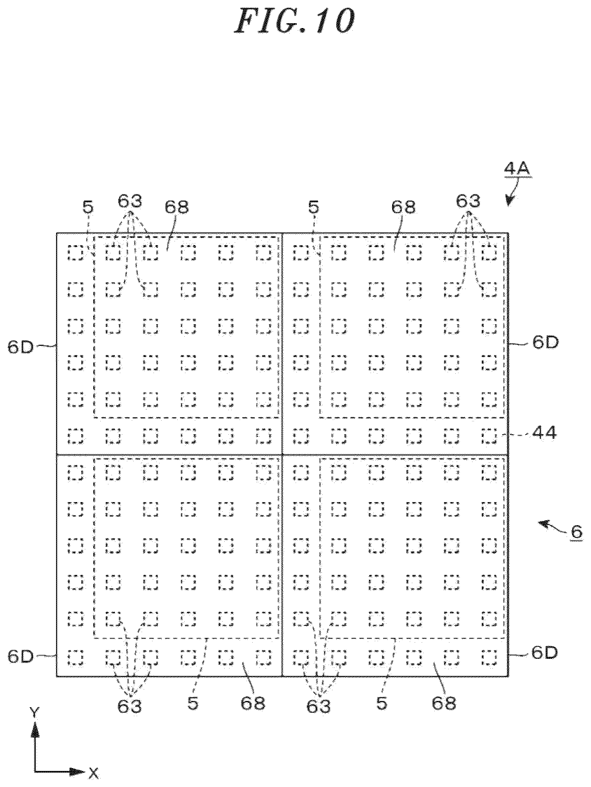

The difference between the floor 4 and a floor 4A that is a first modification of the floor will be described with reference to the vertical side view of FIG. 9 and the plan view of FIG. 10. In the floor 4A, the laminated substrate 6 includes divided pieces 6D of which size is different from those of the divided pieces 6A to 6C. The divided piece 6D has a rectangular shape in plan view, and is provided for each case body 5 to cover the entire upper surface of the case body 5.

The divided piece 6D is disposed to extend from the upper surface of the case body 5 to the upper surface of the portion of the lattice beam 44 that is adjacent to the case body 5. The driving coils 7 and the Hall elements 63 are provided at the portion of the divided piece 6D that covers the case body 5 and at the portion of the divided piece 6D that covers the lattice beam 44, and the driving coils 7 and the Hall elements 63 are positioned on the floor 4A in the same layout as that on the floor 4.

The other end of the cable 58, of which one end is connected to each of the upper divided piece 68 and the lower divided piece 69 that form the divided piece 6D, is drawn into the storage space 56 of the case body 5 below the divided piece 6D, and is connected to the control substrate 56. In other words, the divided piece 6D is connected to the control substrate 56, similarly to the divided piece 6A of the floor 4. Since the divided piece 6D is formed to extend from the case body 5 to the lattice beam 44 as described above, the operations of the driving coils 7 and the Hall elements 63 located on the lattice beam 44 can also be controlled by the control substrate 56 in the case body 5. Therefore, the control substrate 57 that is provided outside the housing 31 to control the individual elements of the divided pieces 6B and 6C is not provided in the first modification.

Further, if the position where one end of the cable 58 that connects the control substrate 56 and the divided piece 6D is connected to the divided piece 6D overlaps the lattice beam 44 in plan view, the cable 58 may be disposed to extend from the position on the lattice beam 44 toward the position on the case body 5 and to be drawn into the case body 5 from the position on the case body 5. Due to the above-described arrangement, the other end of the cable 58 may be connected to the control substrate 56 in the case body 5.

### <Second Modification of Floor>

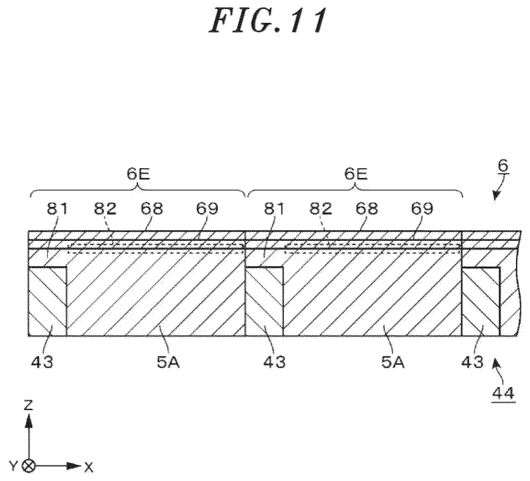

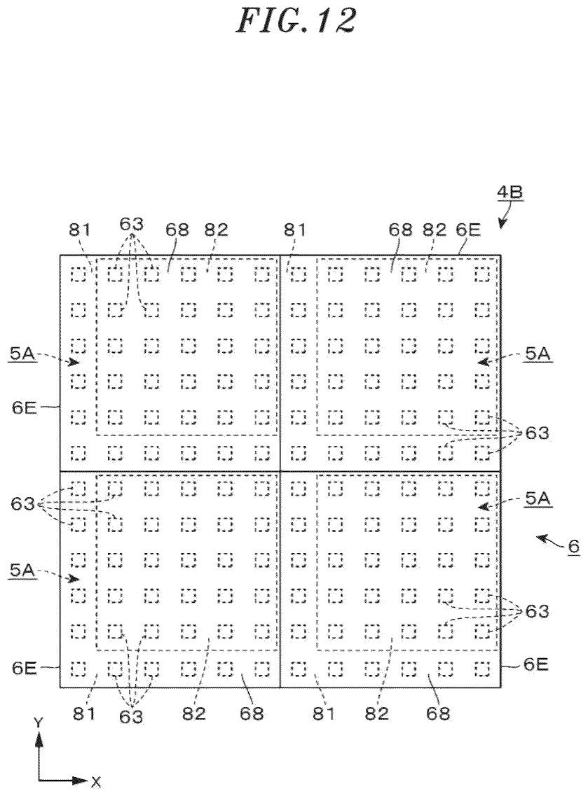

The difference between the floor 4A and a floor 4B that is a second modification of the floor will be described with reference to the longitudinal side view of FIG. 11 and the plan view of FIG. 12. The floor 4B has the case body 5A instead of the case body 5. The case body 5A has a shape different from that of the above-described case body 5. The case body 5A is different from the case body 5 in that the case body 5A does not have the flange 51, and instead, the upper part of the sidewall projects outward from the case body 5A to form a protrusion 81. To be specific, two adjacent sides of the sidewall of the case body 5A, which form the sides of a square in plan view, project laterally, thereby forming the protrusion 81 having an L shape in plan view. In other words, unlike the flange 51 formed by the projection of the entire circumference of the sidewall, the protrusion 81 is formed by the projection of a part of the sidewall. Due to the presence of the protrusion 81, the case body 5A has a rectangular shape in plan view. In the rectangular region, the region that overlaps the sidewall in plan view and the square region surrounded by the sidewall are set as a main body region 82. In other words, the region of the upper part of the case body 5A that is not formed as the protrusion 81 serves as the main body region 82, and the main body region 82 overlaps the through-hole 45 in plan view.

In the case body 5A, the bottom surface of the protrusion 81 is connected to the upper surface of the lattice beam 44, and they are fixed to each other by the screws 53, for example, similarly to the case body 5. Further, the case body 5A may be attached to the lattice beam 44 by inserting the lower part of the case body 5A into the through-hole 45 of the frame 41 from the top, or by tilting the case body 5A so that the protrusion 81 can pass through the through-hole 45 from the bottom to the top.

In the floor 4B, the laminated substrate 6 is divided into divided pieces 6E. The divided piece 6E has a rectangular shape in plan view, and is provided for each case body 5A to cover the entire upper surface of the case body 5A. In other words, the divided piece 6E is disposed to extend from the upper surface of the main body region 82 to the upper surface of the protrusion 81. In the divided piece 6E, the driving coils 7 and the Hall elements 63 are disposed at the portion that covers the main body region 82 and at the portion that covers the protrusion 81 (which is also the portion that covers the lattice beam 44). Accordingly, the driving coils 7 and the Hall elements 63 are arranged on the floor 4B in the same layout as that on the floor 4.

Further, similarly to the divided piece 6D of the first modification, the divided piece 6E is connected via the cable 58 to the control substrate 56 disposed in the storage space 55 of the case body 5A below the divided piece 6E. Since the entire bottom surface of the divided piece 6E is in contact with the upper surface of the case body 5A, the divided piece 6D can be effectively cooled by cooling the case body 5A with the cooling mechanism of the case body 5A.

As illustrated in the example of the floor 4B, the Hall element 63 may be provided at a portion of the case body that overlaps the lattice beam 44, instead of being provided at the lattice beam 44. The Hall elements 63 may be provided in the case body as described above, or may be provided above the case body. From the above, the Hall elements 63 may be provided at positions that overlap the lattice beam 44 and positions that overlap the through-holes 45 formed by the lattice beam 44 in plan view.

In each of the above examples, the divided piece is provided for each case body. However, the present disclosure is not limited to such a configuration, and divided pieces may be formed across a plurality of case bodies. Further, although the configuration in which the case body blocks the square through-holes 45 formed by the lattice beam 44 has been described, the present disclosure is not limited to such a configuration. The floor may be formed by boring through-holes having a circular shape in plan view at intervals in a floor plate forming the bottom wall of the housing, and providing the case body 5 having a circular shape in plan view in each through-hole to block each through-hole. Further, the Hall elements 63 may be provided in the outer area of the through-holes in the floor plate and above the case body 5, for example, similarly to the floor 4. Due to such a configuration, the floor does not necessarily have a structure having a lattice beam.

Further, the through-holes provided in the floor are not necessarily blocked by the case body. For example, the through-holes may be blocked from the upper side of the floor by a plate larger than the through-holes. The laminated substrate 6 may be provided on the plate, and the control substrate 56 may be disposed below the plate. Further, although the Hall element is illustrated as the magnetic sensor, a sensor other than the Hall element, such as a magnetoresistance (MR) sensor, may be used as long as it can detect the magnetic force. Further, the magnet 23 provided at the moving body 2 is not limited to a permanent magnet, and may be an electromagnet. In the above example in which the electromagnets are provided on the floor, the winding axis extends horizontally. However, the present disclosure is not limited to the case of using the electromagnets. A plurality of electromagnets of which winding axes extend vertically may be distributed on the floor.

In each of the above examples, the floor 4 is provided with the plurality of through-holes 45 and the plurality of case bodies 5, and the beams 43 are provided between the case bodies 5. However, only one relatively large through-hole 45 and only one relatively larger case body 5 may be provided. Specifically, for example, the lattice beam 44 is not provided in the outer frame 42 shown in FIG. 5, and only one case body 5 may be provided to block the through-hole formed by the outer frame 42. In this case, the Hall elements 63 are provided in or on the case body 5, and at a position overlapping the outer frame 42 surrounding the case body 5 in plan view. In addition, although the case in which the Hall elements 63 are located at the respective lattice points of a square lattice has been described, they may be located at the lattice points of a rectangular lattice. Therefore, the positions are not necessarily located at the lattice points of a square lattice, and may be located at the lattice points of a rectangular lattice.

In the above description of the case in which the wafer W as a substrate is transferred in the transfer system 14, the substrate to be transferred is a semiconductor manufacturing substrate. The semiconductor manufacturing substrate herein includes, in addition to the wafer W, a substrate used in a semiconductor manufacturing process, and also includes a flat panel display manufacturing substrate. The flat panel display (FPD) manufacturing substrate include a substrate used for various FPDs such as a liquid crystal display, a plasma display, an organic electroluminescence (EL) display, a field emission display, or an electronic paper, and a substrate used in a FPD manufacturing process. The substrate used in the semiconductor manufacturing process and the substrate used in the FPD manufacturing process include a substrate that is a photomask used in an exposure process during the respective manufacturing processes, and a dummy substrate that is processed for parameter setting or testing in a substrate processing apparatus.

The embodiments of the present disclosure are illustrative in all respects and are not restrictive. The above-described embodiments may be omitted, replaced, or changed in various forms without departing from the scope of the appended claims and the gist thereof.

1. A transfer system used in a semiconductor manufacturing device in which a moving body having a magnet moves while being levitated from a floor by a magnetic force to transfer a substrate to a processing module for processing the substrate, comprising:
a through-hole forming member having a through-hole formed in a vertical direction;
a blocking member that blocks the through-hole to form the floor;
a housing of which bottom wall serving as the floor and of which inside is evacuated to create a vacuum atmosphere in a moving area of the moving body that is formed on the floor;
an electromagnet provided inside the floor to move the moving body; and
a magnetic sensor disposed inside the floor at positions overlapping the through-hole forming member and the blocking member in plan view, and configured to detect a magnetic force of the magnet.

2. The transfer system of claim 1, wherein the magnetic sensors overlapping the through-hole forming member and the magnetic sensors overlapping the blocking member are located at lattice points of a rectangular lattice in plan view.

3. The transfer system of claim 2, wherein the magnetic sensors overlapping the through-hole forming member and the magnetic sensors overlapping the blocking member are located at the same height.

4. The transfer system of claim 3, wherein the respective electromagnets are disposed above the respective magnetic sensors.

5. The transfer system of claim 4, wherein a plurality of the through-holes and a plurality of the blocking members are provided, and
the through-hole forming member has a lattice beam.

6. The transfer system of claim 5, wherein the blocking member is a case body having therein a storage space, and
a control device for the plurality of electromagnets and the magnetic sensors is included in the storage space.

7. The transfer system of claim 6, wherein a first substrate laminated on the case body and the lattice beam, and having the magnetic sensors,
a second substrate laminated on the first substrate and having the plurality of electromagnets, and
the plurality of electromagnets are provided at positions overlapping the lattice beam and at positions overlapping the through-holes in plan view.

8. The transfer system of claim 7, wherein the first substrate includes a plurality of first divided pieces, each being provided with the magnetic sensors, and
the second substrate includes a plurality of second divided pieces, each being provided with the electromagnets.

9. The transfer system of claim 8, wherein an upper surface of the case body is inserted into the through-hole in plan view,
the first divided piece and the second divided piece include one divided piece covering the upper surface of the case body and another divided piece covering the lattice beam,
said one divided piece is connected to the control device in the storage space, and
the control device connected to the other divided piece is provided outside the storage space.

10. The transfer system of claim 8, wherein the upper surface of the case body is inserted into the through-hole in plan view, and
the first divide piece and the second divided piece are provided for each case body, and are formed to extend from the upper surface of the case body to an upper surface of the lattice beam.

11. The transfer system of claim 8, wherein an upper part of a sidewall of the case body has a protrusion that protrudes laterally and covers the lattice beam from the top, and
the first divided piece and the second divided piece are provided for each case body, and are formed on the upper surface of the case body to extend from an area overlapping the through-holes to the protrusion.

12. A semiconductor manufacturing method in which a moving body having a magnet moves while being levitated from a floor by a magnetic force to transfer a substrate to a processing module for processing the substrate, comprising:
evacuating a housing of which bottom wall serves as the floor formed by blocking a through-hole of a through-hole forming member that is formed in a vertical direction with a blocking member, and creating a vacuum atmosphere in a moving area of the moving body that is formed on the floor;
moving the moving body by an electromagnet provided on the floor; and
detecting a magnetic force of the magnet by a magnetic sensor provided at positions overlapping the blocking member and the through-hole forming member in plan view.
